(19) United States
(12) Patent Application Publication
(10) Pub. No.: US 2012/0292637 A1
(43) Pub. Date: Nov. 22, 2012

(54) Dual Cavity Etch for Embedded Stressor Regions

(75) Inventors: Sven Beyer, Dresden (DE); Peter Baars, Dresden (DE); Jan Hoentschel, Dresden (DE); Thilo Scheiper, Dresden (DE)

(73) Assignee: GLOBALFOUNDRIES INC., Grand Cayman (KY)

(21) Appl. No.: 13/109,134

(22) Filed: May 17, 2011

(51) Int. Cl. H01L 27/092; H01L 21/336; H01L 21/8238; H01L 21/20

(52) U.S. Cl. 257/77; 438/478; 438/285; 438/199; 257/E21.09; 257/E21.409; 257/E21.632; 257/E27.062

(57) ABSTRACT

Generally, the present disclosure is directed to methods for forming embedded stressor regions in semiconductor devices such as transistor elements and the like. One illustrative method disclosed herein includes forming a first material in first cavities formed in a first active area adjacent to a first channel region of a semiconductor device, wherein the first material induces a first stress in the first channel region. The method also includes, among other things, forming a second material in second cavities formed in a second active area adjacent to a second channel region of the semiconductor device, wherein the second material induces a second stress in the second channel region that is of an opposite type of the first stress in the first channel region, and wherein the first and second cavities are formed during a common etch process.

### BACKGROUND OF THE INVENTION

1. Field of the Invention

Generally, the present invention relates to sophisticated integrated circuits, and, more particularly, to utilizing embedded stressor regions to enhance the performance of semiconductor devices such as transistor elements and the like.

2. Description of the Related Art

In modern ultra-high density integrated circuits, device features have been steadily decreasing in size to enhance the performance of the semiconductor device and the overall functionality of the circuit. In addition to an increase in the speed of operation due to reduced signal propagation times, reduced feature sizes allow an increase in the number of functional elements in the circuit in order to extend its functionality. Today, advanced semiconductor devices may include features having a critical size of 32 nm or even less.

The fabrication of integrated circuits requires the formation of a large number of circuit elements on a given chip area according to a specified circuit layout. Generally, a plurality of process technologies are currently practiced, wherein, for complex circuitry, such as microprocessors, storage chips and the like, CMOS technology is currently the most promising approach, due to the superior characteristics in view of operating speed and/or power consumption. During the fabrication of complex integrated circuits using CMOS technology, millions of complementary transistors, i.e., N-channel (NMOS) transistors and P-channel (PMOS) transistors, are formed on a substrate including a crystalline semiconductor layer. A MOS transistor, irrespective of whether an N-channel transistor or a P-channel transistor is considered, comprises so-called PN junctions that are formed by an interface of highly doped drain and source regions with an inversely doped channel region disposed between the drain region and the source region. The conductivity of the channel region, i.e., the drive current capability of the conductive channel, is controlled by a gate electrode formed above the channel region and separated from the channel by a thin gate insulating layer, or gate dielectric. In operation, an appropriate control voltage is applied to the gate electrode, which thereby forms a conductive channel below the gate electrode. The conductivity of the channel region depends on several factors, including dopant concentration, the mobility of the charge carriers, and, for a given extension of the channel region in the transistor width direction, on the distance between the source and drain regions, which is also referred to as channel length. Therefore, in combination with the capability of rapidly creating a conductive channel below the insulating layer upon application of the control voltage to the gate electrode, the conductivity of the channel region substantially determines the performance of the MOS transistors. Thus, the reduction of the channel length, and the commensurate reduction of the channel resistivity, renders the channel length a dominant design criteria for accomplishing an increase in the operating speed of the integrated circuits.

The continuous shrinkage of the transistor dimensions, however, carries with it a plurality of issues which have to be addressed so as to not unduly offset the advantages that may be obtained by steadily decreasing the channel length of MOS transistors, such as the development of enhanced photolithography and etch strategies necessary to reliably and reproducibly create circuit elements having very small critical dimensions for new device generations. Given the general processing difficulties associated the continuous size reduction of the critical dimensions, i.e., the gate length of the transistors, other mechanisms have been utilized in an effort to increase charge carrier mobility in the channel region of transistor elements and thereby enhance overall device performance. For example, in one approach, the dopant concentration within the channel region may be reduced, thereby reducing scattering events for the charge carriers and thus increasing the conductivity. However, reducing the dopant concentration in the channel region significantly affects the threshold voltage of the transistor device, thereby making a reduction of the dopant concentration a less attractive approach unless other mechanisms are developed to adjust a desired threshold voltage. In another approach, the lattice structure in the channel region may be modified, for instance by creating tensile or compressive stress, which results in a modified mobility for electrons and holes. For example, creating a tensile stress in the channel region increases the mobility of electrons, wherein, depending on the magnitude of the tensile stress, an increase in mobility of up to 20% may be obtained, which, in turn, may directly translate into an increased channel conductivity and a corresponding improvement in NMOS transistor performance. On the other hand, a compressive stress in the channel region may increase the mobility of holes, thereby providing the potential for enhancing the performance of PMOS transistors.

One common approach for inducing a desired level of stress in the channel region of some semiconductor devices is through the use of a stressed overlayer. In practice, the stressed overlayer—i.e., a material layer having an intrinsic internal stress—is formed above the transistor elements, and the intrinsic stress of the stressed overlayer is transferred through the gate electrode and any sidewall spacer elements to the channel region below the gate dielectric layer. The stressed overlayer method, however, has some inherent drawbacks. For example, once formed, the stressed overlayer must typically remain in place throughout all remaining process steps, so that the beneficial stress imparted to the channel region by the stressed overlayer is maintained in the final device configuration. Furthermore, the presence of any intermediate device elements or material layers between a stressed overlayer and the targeted channel region of a MOS transistor—such as the aforementioned gate electrode, sidewall spacer elements, and gate dielectric layer—may tend to mitigate the level of stress than can be transferred through those elements or layers to the channel. Additionally, since the type of intrinsic stress used to increase hole mobility along the channel length of PMOS transistor elements (i.e., a compressive stress) differs from the type of stress used to increase electron mobility along the channel length of NMOS transistor elements (i.e., a tensile stress), different materials and deposition parameters may be required to form each type of stressed overlayer. Moreover, sophisticated photolithography and/or etching techniques may also be necessary to facilitate the formation of stressed overlayers, thus increasing overall processing complexity and costs, while potentially reducing product yield.

In view of the processing complexity and reliability concerns cited above, it would therefore be highly desirable to eliminate or at least reduce some of the problems generally associated with using stressed material overlayers to enhance the speed and/or performance of sophisticated transistor devices. The presently disclosed subject matter is therefore directed to methods for forming embedded stressor regions that may solve or at least reduce one or more of the problems identified herein.

### SUMMARY OF THE DISCLOSURE

The following presents a simplified summary of the present disclosure in order to provide a basic understanding of some aspects disclosed herein. This summary is not an exhaustive overview of the disclosure, nor is it intended to identify key or critical elements of the subject matter disclosed here. Its sole purpose is to present some concepts in a simplified form as a prelude to the more detailed description that is discussed later.

Generally, the present disclosure is directed to methods for forming embedded stressor regions in semiconductor devices such as transistor elements and the like. One illustrative method disclosed herein includes forming a first material in first cavities formed in a first active area adjacent to a first channel region of a semiconductor device, wherein the first material induces a first stress in the first channel region. The method also includes, among other things, forming a second material in second cavities formed in a second active area adjacent to a second channel region of the semiconductor device, wherein the second material induces a second stress in the second channel region that is of an opposite type of the first stress in the first channel region, and wherein the first and second cavities are formed during a common etch process.

In another illustrative embodiment, a method includes, among other things, forming a first gate electrode structure above a first active area and a second gate electrode structure above a second active area of a semiconductor device, and forming first and second cavities adjacent to first and second channel regions below the first and second gate electrode structures, respectively, during a common etch process. The disclosed method also includes forming a first stressed semiconductor material in the first cavities, the first stressed semiconductor material inducing a first type of stress in the first channel region, and forming a second stressed semiconductor material in the second cavities, the second stressed semiconductor material inducing a second type of stress in the second channel region that is opposite of the first type of stress in the first channel region.

Also disclosed herein is yet another illustrative method that includes forming first cavities in an active area of an NMOS transistor element, wherein the first cavities are formed on either side of a channel region of the NMOS transistor element. The method also includes forming second cavities in an active area of a PMOS transistor element, wherein the second cavities are formed on either side of a channel region of the PMOS transistor element, and wherein the first and second cavities are formed during a common etch process. Furthermore, the disclosed method includes, among other things, forming a silicon-carbon semiconducting material in the first cavities, the silicon-carbon semiconducting material creating a tensile stress in the channel region of the NMOS transistor element, and forming a silicon-germanium semiconducting material in the second cavities, the silicon-germanium semiconducting material inducing a compressive stress in the channel region of the PMOS transistor element.

An illustrative semiconductor device disclosed herein includes a PMOS transistor element, the PMOS transistor element including a first gate electrode structure, a first gate dielectric layer, and a first channel region. The illustrative semiconductor device further includes a silicon-germanium material region at least partially embedded in a first active area of the semiconductor device on opposites sides of the first gate electrode structure, wherein the silicon-germanium material region extends to a first depth below the gate dielectric layer and is adapted to induce a compressive stress in the first channel region. The semiconductor device also includes, among other things, an NMOS transistor element, the NMOS transistor element including a second gate electrode structure, a second gate dielectric layer, and a second channel region. Also included in the disclosed semiconductor device is a silicon-carbon material region at least partially embedded in a second active area of the semiconductor device on opposites sides of the second gate electrode structure, wherein the silicon-carbon material region extends to a second depth below the gate dielectric layer and is adapted to induce a tensile stress in the second channel region, and wherein the second depth is substantially the same as the first depth.

### BRIEF DESCRIPTION OF THE DRAWINGS

The disclosure may be understood by reference to the following description taken in conjunction with the accompanying drawings, in which like reference numerals identify like elements, and in which:

FIGS. 1a-1l schematically illustrate a process flow of illustrative embodiments of the subject matter disclosed herein.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the present subject matter are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

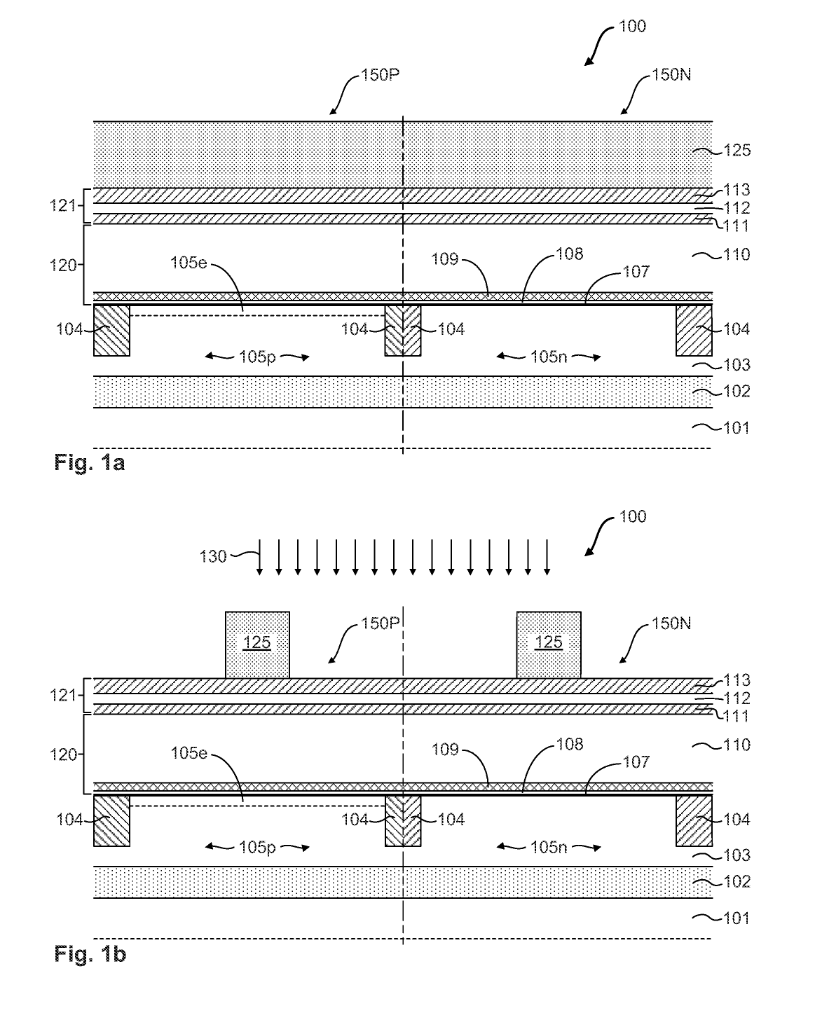

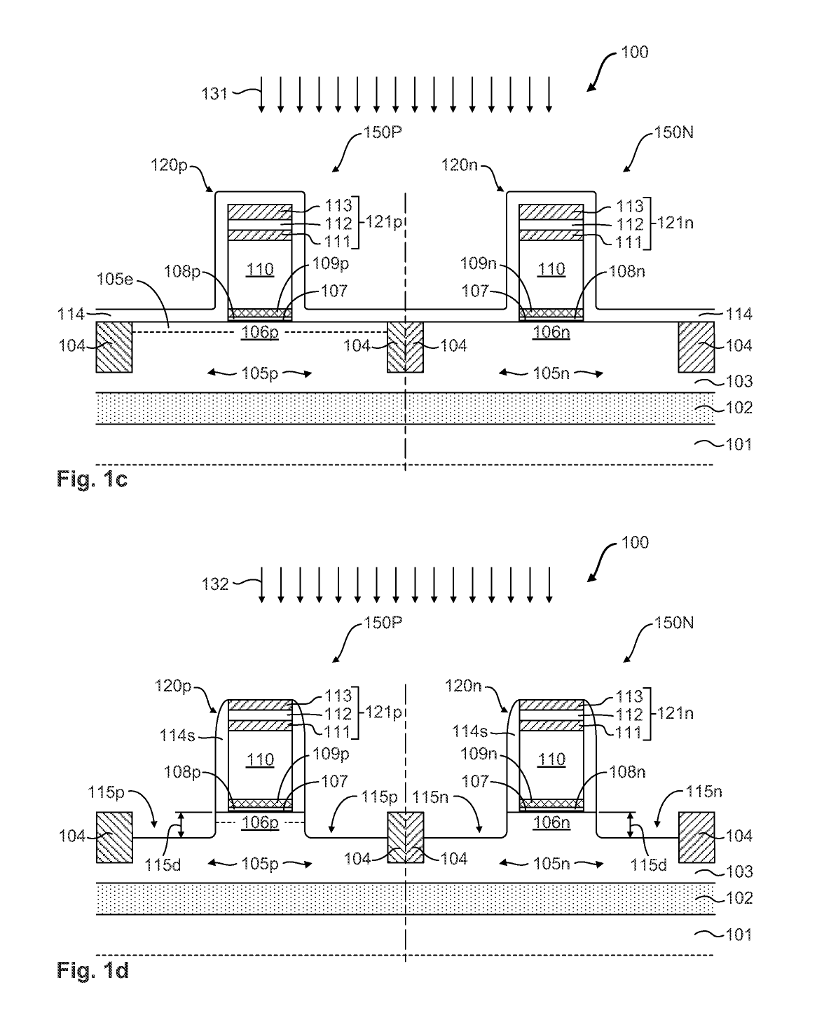

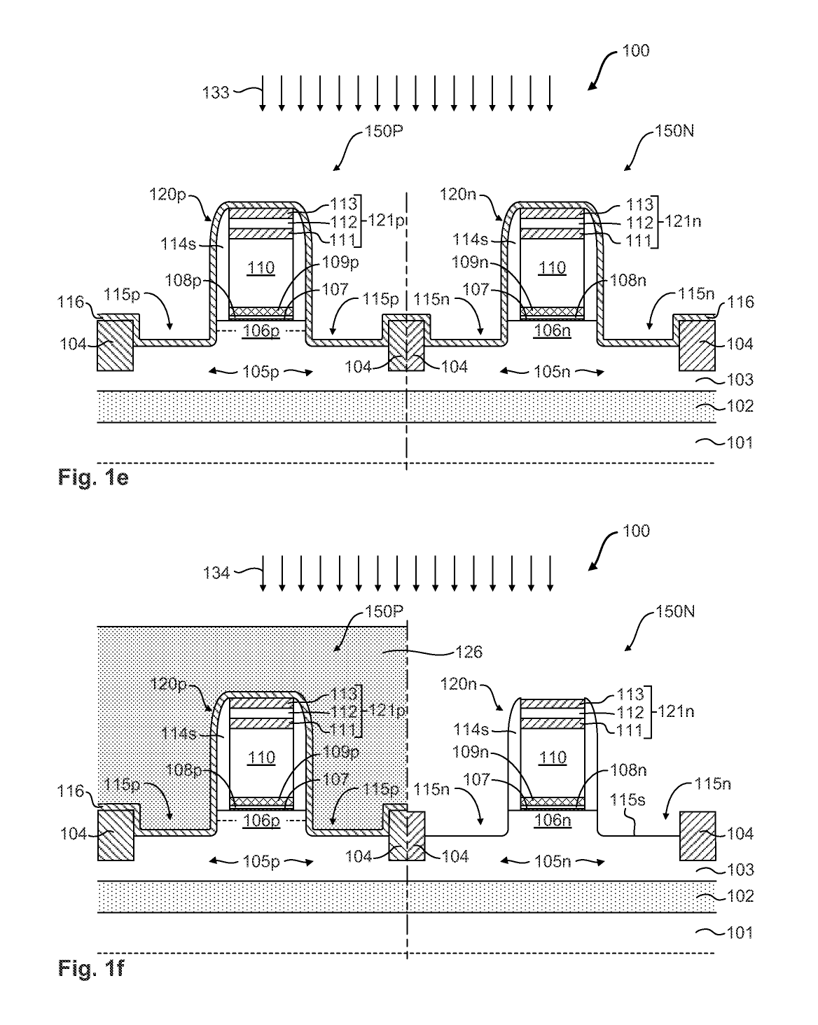

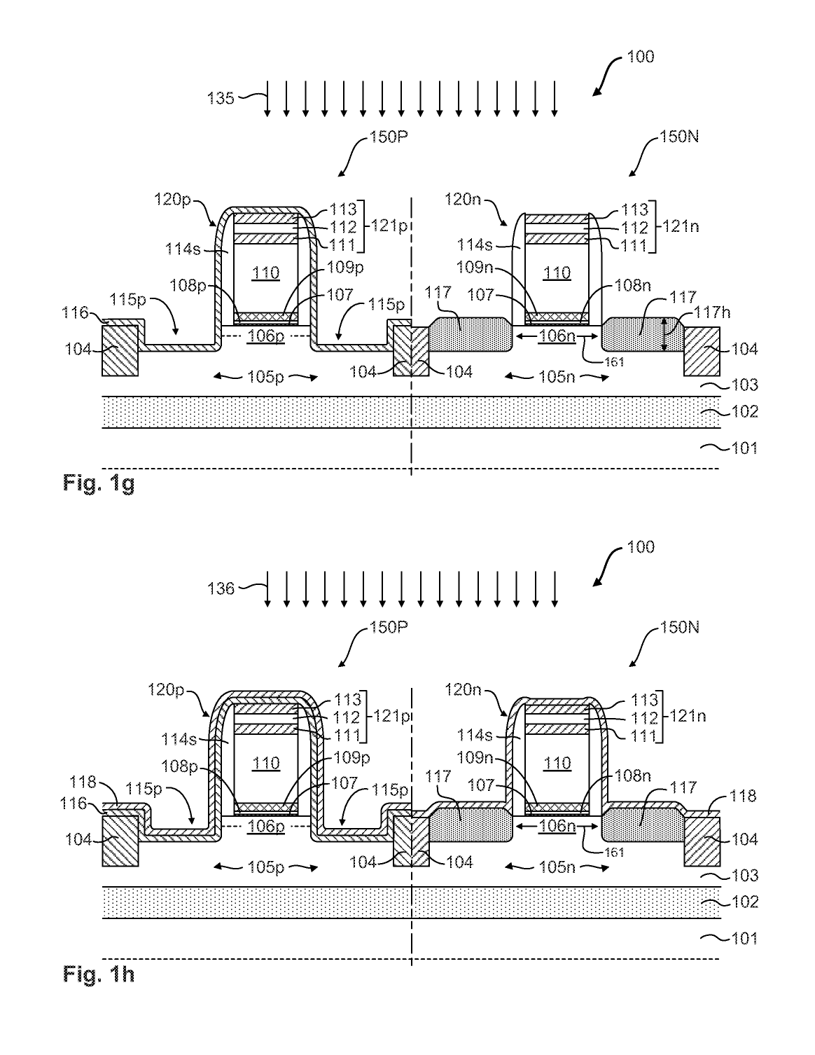

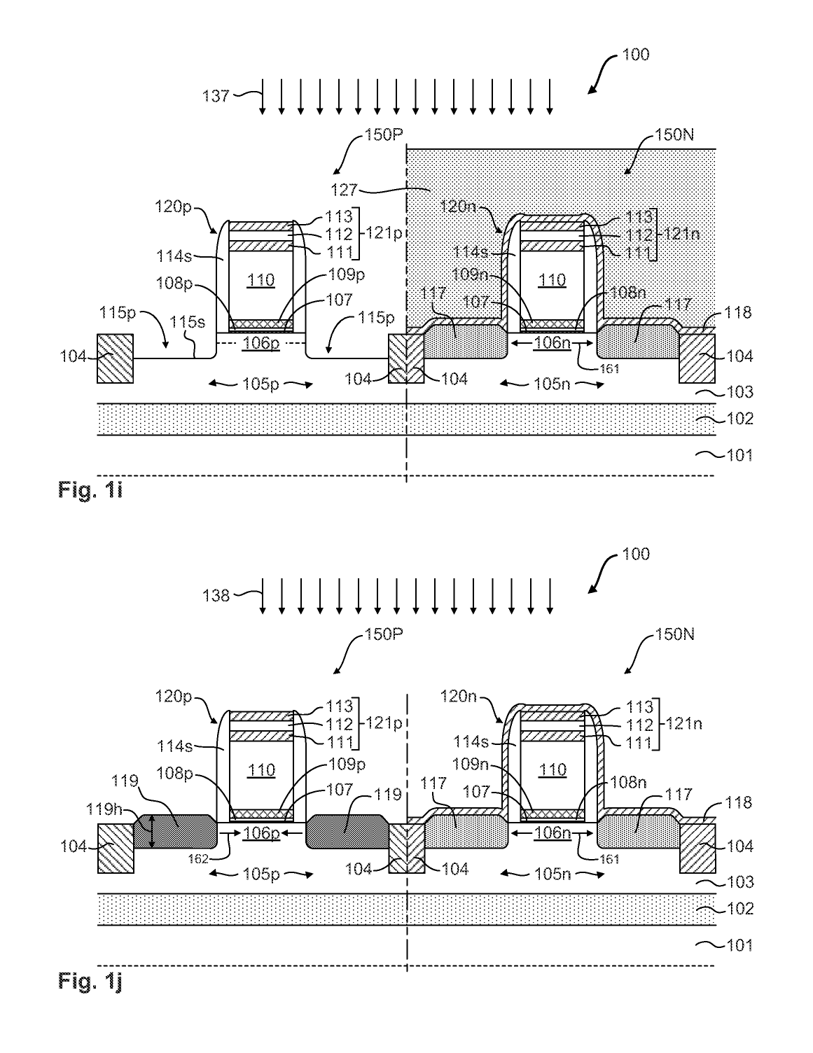

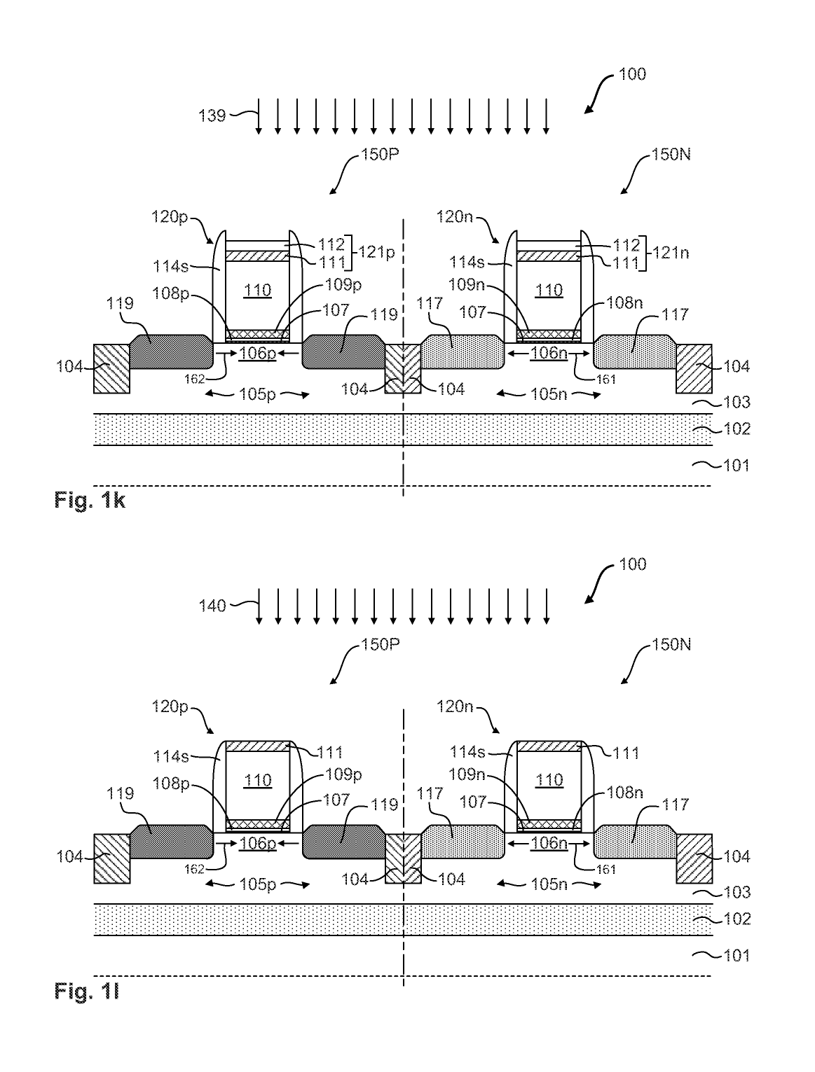

Furthermore, it should be understood that, unless otherwise specifically indicated, any relative positional or directional terms that may be used in the descriptions below—such as “upper,” “lower,” “on,” “adjacent to,” “above,” “below,” “over,” “under,” “top,” “bottom,” “vertical,” “horizontal,” and the like—should be construed in light of that term's normal and everyday meaning relative to the depiction of the components or elements in the referenced figures. For example, referring to the schematic cross-section of the semiconductor device 100 depicted in FIG. 1d, it should be understood that the gate electrode structures 120n and 120p are formed “above” the active areas 105n and 105p, respectively, and that the substrate 101 is positioned “below” or “under” the semiconductor layer 103. Similarly, it should also be noted that sidewall spacers 114 are positioned “adjacent to” the sidewalls of the conductive material layers 110, whereas in special cases, the spacers 114 may be positioned “on” the sidewalls of the conductive material layers 110 in those embodiments wherein no other layers or structures are interposed therebetween.

FIG. 1a shows a schematic cross-sectional view of an illustrative semiconductor device 100 during an initial manufacturing stage. As shown in FIG. 1a, the semiconductor device 100 may comprise a substrate 101, which may represent any appropriate carrier material for having formed thereon or thereabove a semiconductor layer 103. In some illustrative embodiments, the substrate 101 may be a substantially crystalline substrate—i.e., a bulk semiconductor material—and the semiconductor layer 103 may be formed on or be part of the substantially crystalline substrate 101. In other embodiments, the substrate 101 and the semiconductor layer 103 may define a silicon-on-insulator (SOI) architecture, in which a buried insulating layer 102 may be provided below the semiconductor layer 103, as illustrated in FIG. 1a. In certain embodiments, the thickness of the buried insulating layer 102 may be in the range of approximately 100-150 nm, and in one embodiment may be approximately 130 nm. The thickness of the semiconductor layer 103, on the other hand, may range from approximately 60 nm to 100 nm, whereas in certain embodiments may the semiconductor layer 103 may be approximately 88 nm. Depending on device requirements, the buried insulating layer 102 may comprise an appropriate silicon-based dielectric material, such as, for example, silicon dioxide and the like, which may sometimes be referred to as a buried oxide layer, or BOX layer. Furthermore, it should also be appreciated that the device 100 may comprise an SOI configuration in some device areas and a bulk semiconductor configuration in other device areas, as may be appropriate to the overall device design requirements and/or processing parameters.

The semiconductor device 100 may comprise device regions 150N and 150P, representing, for example, regions in which NMOS and PMOS transistor elements, respectively, may be formed during later manufacturing stages, as will be discussed in further detail below. The device regions 150N and 150P may include active areas 105n and 105p, respectively, which may in turn be defined and enclosed by isolation structures 104, as illustrated in FIG. 1a. In certain illustrative embodiments, the isolation structures 104 may be provided in the form of a shallow trench isolation, as may typically be used for sophisticated integrated circuits. Additionally, the active areas 105n, 105p may also include an appropriate dopant species for establishing the requisite conductivity type. For example, a p-type dopant, such as boron, may be incorporated into the active area 105n so as to form a p-well, in and above which may be formed NMOS transistor elements. On the other hand, an n-type dopant, such as phosphorous or arsenic, and the like, may be incorporated into the active area 105p, thereby forming an n-well in and above which PMOS transistors may be formed.

It should also be noted that, depending on the device type and operating requirements, at least an upper portion of the active area in and above which some transistor elements are formed may comprise a semiconductor material that is different than that of the semiconductor layer 103. Such a configuration may be required when a specific work function difference between a metal gate electrode structure and the material of the underlying channel region of a MOS transistor element is necessary for a desired transistor threshold voltage. For example, in device regions wherein high-k dielectric/metal gate electrode PMOS transistor elements may be formed—such as the device region 150P—an upper portion of the active area 105p may comprise a region or layer 105e of silicon-germanium material when a gate-first integration process is used. In some embodiments, the germanium content of the layer 105e may range from 20-30% by weight, and in specific embodiments may be close to approximately 30%. The silicon-germanium layer 105e may be formed in any manner known to those having skill in the art, such as, for example, by an epitaxial growth/deposition process (hereinafter, epitaxial deposition), and the like. In certain illustrative embodiments, the silicon-germanium layer 105e may be formed in the active area 105p of the device region 150P prior to forming the trench isolation structures 104.

As shown in FIG. 1a, a gate electrode stack 120 may also be formed in the device regions 150N, 150P and above the active areas 105n, 105p, respectively, from which gate electrode structures 120n, 120p (see FIGS. 1b-1c) may be patterned during later manufacturing stages, as described below. The gate electrode stack 120 may comprise a plurality of layers and materials, depending on the desired transistor element types and overall integration scheme. For example, in some illustrative embodiments, transistor architecture may be based on a conventional gate insulating layer and polysilicon gate electrode (polySiON) configuration, wherein the materials comprising the gate electrode stack 120 are adapted accordingly. On the other hand, transistor architecture may be based on a more advanced high-k dielectric and metal gate electrode (HK/MG) configuration as shown in the illustrative embodiment depicted in FIG. 1a, and which will now be described.

In some embodiments of the present disclosure, a base insulating layer 107 may be formed above the semiconductor layer 103 when advanced HK/MG transistor element configurations are contemplated. The base insulating layer 107 may have and thickness of approximately 1-2 nm and may comprise, for example, silicon dioxide, which, in some illustrative embodiments may be formed by exposing the semiconductor layer 103 to an appropriately designed wet chemical oxidation process. Furthermore, in certain illustrative embodiments, nitrogen atoms may thereafter be introduced into the base insulating layer 107 during a nitridization step, which may in some cases form an oxynitride material. Next, a gate insulation layer 108 may be formed above the base insulating layer 107 using, for example, a ALD or PVD deposition process. Depending on device design requirements, the gate insulation layer 108 may range in thickness between 1 nm and 5 nm, and may comprise one or more of several well-known high-k gate dielectric materials (i.e., materials having a dielectric constant “k” greater than 10), such as tantalum oxide (Ta₂O₅), strontium titanium oxide (SrTiO₃), hafnium oxide (HfO₂), hafnium silicon oxide (HfSiO), zirconium oxide (ZrO₂) and the like. Moreover, the specific material and/or materials comprising the gate insulation layer 108 in the device region 150N, wherein NMOS transistor elements will be formed, may be different than that of the gate insulation layer 108 in the device region 150P, wherein PMOS transistor elements will be formed. For example, in one illustrative embodiment, the gate insulation layer 108 in the NMOS device region 150N may comprise lanthanum ions implanted in a hafnium oxide layer, whereas in the PMOS device region 150P, the gate insulation layer 108 may comprise aluminum ions implanted in a hafnium oxide material layer. Depending on the desired work function of the final high-k/metal gate electrode, other material types and combinations may also be used for the high-k dielectric gate insulation layer 108 and/or ion implantation.

As shown in FIG. 1a, a layer of metal gate material 109 may then be formed above the gate insulation layer 108 using a suitably designed deposition process, such as PVD, CVD and the like. Depending on the desired work function and threshold voltage requirements of the final gate electrode structures 120n and 120p (see, FIGS. 1c-1l), the layer of metal gate material 109 may comprise, for example, one or more of several metal gate materials well known in the art, such as titanium nitride (TiN), titanium-aluminum (TiAl), titanium aluminum nitride (TiAlN), titanium silicon nitride (TiSiN) and the like, as well as combinations thereof. Thereafter, the gate electrode stack 120 may be completed by forming a layer of conductive material 110, e.g., polysilicon, above the layer of metal gate material 109, wherein the thickness of the conductive material layer 110 may be as required to adjust the finished height of the gate electrode structures 120n and 120p (see, FIG. 1c-1l). In some illustrative embodiments, a thin layer of aluminum (not shown) may be formed on the layer of metal gate material 109 so as to facilitate the formation of the conductive material layer 110.

As noted previously, in some illustrative embodiments of the subject matter disclosed herein the materials and layers comprising the gate electrode stack 120 may adjusted from the HK/MG configuration described above when a conventional polySiON gate electrode configuration is contemplated. For example, in certain illustrative embodiments, the high-k dielectric gate insulation layer 108 and the layer of metal gate material 109 that may be specific to the HK/MG configuration may be omitted from the gate electrode stack 120. Furthermore, in a conventional polySiON gate electrode configuration, the base insulating layer 107 may serve as the gate insulation layer of the finished transistor element, the thickness and material of which may be adjusted as necessary for the desired work function and threshold voltage. For example, in some embodiments the base insulating layer 107 may comprise silicon dioxide and/or silicon oxynitride, with a thickness ranging from 1-5 nm. The conductive material layer 110, e.g., polysilicon, may thereafter be formed above the base insulating layer 107 without the high-k dielectric gate insulation layer 108 and metal gate material layer 109 formed therebetween.

After completion of the gate electrode stack 120, an illustrative cap layer stack 121 may then be formed above the conductive material layer 110 so as to cover the gate electrode structures 120n, 120p (see, FIGS. 1c-1l) during subsequent manufacturing steps, as will be described in further detail below. In some illustrative embodiments, the cap layer stack 121 may be, for example, an oxide-nitride-oxide (ONO) material stack, comprising a first cap layer 111 formed above the conductive material layer 110, a second cap layer 112 formed above the first cap layer 111, and a third cap layer 113 formed above the second cap layer 112. In certain embodiments, the first cap layer 111 may comprise silicon dioxide and have a thickness ranging on the order of 1-10 nm, which may be formed using a suitable deposition process, such as ALD, CVD and the like. The second cap layer 112 may comprise a layer of silicon nitride material that ranges in thickness from 20-30 nm, and which may be deposited using a CVD and/or ALD deposition process. Additionally, the third cap layer 113 of the cap layer stack 121 may comprise a layer silicon dioxide having a thickness of approximately 20-40 nm, which may also be formed using a CVD and/or ALD process. Finally, as shown in FIG. 1a, a layer of photoresist material 125 may be deposited above the cap layer stack 121 so as to facilitate subsequent patterning of the gate electrode structures 120n, 120p (see, FIGS. 1b-1c), as will now be discussed.

FIG. 1b schematically shows the illustrative semiconductor device 100 of FIG. 1a in a further manufacturing stage, wherein the photoresist material layer 125 has been patterned to form mask elements 125 above each of the device regions 150N and 150P. Thereafter, an etch process 130 may be performed so as to etch the cap layer stack 121 and the gate electrode stack 120 using the mask elements 125 as etch mask elements. In some illustrative embodiments, the etch process 130 may be a suitably designed anisotropic etch process, such as, for example, a reactive ion etch (RIE) process. Furthermore, the etch recipe may be adjusted as required during the etch process 130 so as to etch away each of the various materials comprising the cap layer stack 121 and the gate electrode stack 120. In certain embodiments, the base insulating layer 107 may be used as an etch stop or etch indicator layer, at which point the etch recipe of the etch process 130 may be further adjusted so as to selective remove the base insulating layer 107, thereby exposing the upper surfaces of the active areas 150n and 150p.

FIG. 1c schematically illustrates the semiconductor device 100 of FIG. 1b in yet a further manufacturing stage, after completion of the etch process 130 and removal of the mask elements 125. As shown in the illustrative embodiment depicted in FIG. 1c, an NMOS gate electrode structure 120n based on HK/MG architecture—which may comprise a base insulating layer 107, a high-k dielectric gate insulation layer 108n, a metal gate material layer 109n, and a conductive material layer 110, such as polysilicon—has been formed in the device region 150N, above the active area 105n. Additionally, the NMOS gate electrode structure 120n may also include, for example, an ONO cap layer 121n formed above the conductive material layer 110 of the NMOS gate electrode structure 120n, which in certain illustrative embodiments may include the first cap layer 111 (comprising, i.e., silicon dioxide), the second cap layer 112 (comprising, i.e., silicon nitride), and the third cap layer 113 (comprising, i.e., silicon dioxide).

Also as schematically shown in the illustrative embodiment depicted in FIG. 1c, a PMOS gate electrode structure 120p utilizing an HK/MG configuration has also been formed in the device region 150P and above the active area 105p. Similar to the NMOS gate electrode structure 120n, the HK/MG PMOS gate electrode structure 120p may comprises a base insulating layer 107, a high-k dielectric gate insulation layer 108p, a metal gate material layer 109p, and a conductive material layer 110, e.g., polysilicon. Furthermore, in certain illustrative embodiments the PMOS gate electrode structure 120p may also include an ONO cap layer 121p formed above the conductive material layer 110 of the PMOS gate electrode structure 120p, which may comprise the first, second, and third cap layers 111, 112 and 113, respectively, arranged as shown in FIG. 1c.

It should be appreciated that, as described previously, in some illustrative embodiments of the present disclosure, either the NMOS gate electrode structure 120n or the PMOS gate electrode structure 120p may be based on conventional polySiON gate electrode architecture, wherein the base insulating layer 107 serves as the transistor elements' gate insulation layer, and wherein the high-k dielectric gate insulation layers 108n or 108p and the metal gate material layers 109n or 109p may also be omitted from the gate electrode structures 120n or 120p, respectively. Furthermore, in at least one illustrative embodiment, both gate electrode structures 120n and 120p may comprise a conventional polySiON gate electrode configuration.

As shown in FIG. 1c, a spacer layer 114 may also be formed above both the active area 105n of the NMOS device region 150N and active area 105p of the PMOS device region 150P. In some illustrative embodiments, the spacer layer 114 may comprise a suitable insulating material commonly used for forming sidewall spacer elements, such as, for example, silicon nitride and the like, and may have a thickness ranging from approximately 5 nm to 12 nm. Furthermore, in certain embodiments the spacer layer 114 of may be formed using a suitably designed deposition process 131, which may be adapted so as to conformally cover the active areas 105n and 105p as well as the exposed surfaces of the gate electrode structure 120n and 120p, including the sidewall and upper surfaces thereof. For example, in one illustrative embodiment, the deposition process 131 may comprise a first highly conformal deposition process, such as monolayer deposition (MLD), atomic layer deposition (ALD), and the like, which may be used to deposit approximately the first 2-4 nm of the spacer layer 114 in a highly conformal fashion. Furthermore, the deposition process 131 may comprise a second conformal deposition process, such as low pressure chemical vapor deposition (LPCVD) and the like, so as to deposit the remaining 3-8 nm of the spacer layer 114.

FIG. 1d schematically illustrates the semiconductor device 100 of FIG. 1c in a further illustrative processing step. As shown in FIG. 1d, an anisotropic etch process 132, such as, for example, a RIE process and the like, may be performed to form sidewall spacer elements 114s on the sidewalls of the NMOS gate electrode structure 120n and the PMOS gate electrode structure 120p. In some embodiments, the etch recipe of the anisotropic etch process 132 may adapted so as to selective remove the material comprising the spacer layer 114, e.g., silicon nitride. Moreover, due to the anisotropic nature of the etch process 132, the substantially horizontal portions of the spacer layer 114 previously formed above the active areas 105n, 105p and above the third cap layers 113 of the cap layer stacks 121n, 121p may be substantially etched away. On the other hand, the substantially vertical portions of the spacer layer 114 previous formed on or adjacent to the sidewalls of the gate electrode structures 120n, 120p may remain substantially in place, thereby forming sidewall spacer elements 114s as previously noted.

Once the horizontal portions of the spacer layer 114 have been removed from above the semiconductor device 100, the etch recipe of the anisotropic etch process 132 may be adjusted so as to selectively remove a portion of the silicon-based semiconductor material comprising the semiconductor layer 103. Accordingly, as shown in the illustrative embodiment depicted in FIG. 1d, cavities 115n may then be formed in the active area 105n adjacent to and on either side of the channel region 106n below the NMOS gate electrode structure 120n during the anisotropic etch process 132. Additionally, cavities 115p may also be formed in the active area 105p adjacent to and on either side of the channel region 106p below the PMOS gate electrode structure 120p during the anisotropic etch process 132. Moreover, since the cavities 115n and 115p are substantially simultaneously formed in the active areas 105n and 105p, respectively, during a common anisotropic etch process 132, the depth 115d of the cavities 115n, 115p may be substantially the same. In some illustrative embodiments of the present disclosure, such as, for example, when the specific device region 150N or 150P may be based on an SOI (silicon-on-insulator) architecture—i.e., when a buried insulating layer 102 is present—the depth 115d of the cavities 115n, 115p may be limited so as to not encroach on the buried insulating layer 102. Accordingly, in certain embodiments the depth 115d of the cavities 115n, 115p may be in the range of approximately 30-60 nm, whereas in at least one embodiment the depth 115d may be approximately 40 nm. On the other hand, when the semiconductor substrate 101 comprises a bulk crystalline semiconductor material—i.e., when a buried insulating layer 102 is not present—the depth 115d of the cavities 115n, 115p may not be so limited, and as such may range from 50-75 nm or even greater.

Additionally, it should be noted that in certain embodiments, and even though the etch recipe of the anisotropic etch process 132 may be adjusted during this phase so as to be selective to the silicon-based material of the active regions 105n, 105p, the exposed horizontal portions of the third cap layers 113 an the shallow trench isolation structures 104 may also be affected during the etch process 132, and the thickness of each may be commensurately reduced.

FIG. 1e schematically illustrates the semiconductor device 100 of FIG. 1d during a subsequent manufacturing stage. As shown in FIG. 1e, a first conformal dielectric material layer 116 may be formed above the semiconductor device 100 so as to cover the exposed surfaces thereof, including trench isolation structures 104, cavities 115n, 115p, sidewall spacer elements 114s of gate electrode structures 120n, 120p, and third cap layers 113 of cap layer stacks 121n, 121p. In some illustrative embodiments, the first conformal dielectric material layer 116 may comprise, for example, a layer of silicon dioxide material having a thickness in the range of 2-10 nm. Moreover, in certain embodiments the first conformal dielectric material layer 116 may be formed using a highly conformal deposition process 133, such as MLD, ALD, PECVD and the like.

FIG. 1f schematically depicts the illustrative semiconductor device 100 of FIG. 1e in yet a further manufacturing stage, wherein a mask layer 126, such as, for example, a photoresist layer, has been formed above the semiconductor device 100 and patterned so as to cover the PMOS device region 150P and to expose the NMOS device region 150N. As shown in FIG. 1f, the semiconductor device 100 may thereafter be exposed to an etch process 134, which may be adapted so as to be highly selective to the material comprising the first conformal dielectric material layer 116, e.g., silicon dioxide, so as to expose the surfaces 115s of the cavities 115n—i.e., the semiconductor material of the active area 105n. For example, in certain illustrative embodiments disclosed herein, the etch process 134 may comprise a highly selective chemical oxide removal process, recipes for which are known in the art. Additionally, it should be noted that in those embodiments of the present disclosure wherein the third cap layer 113 of the cap layer stack 121n and the trench isolation structures 104 also comprise silicon dioxide, the thickness of those elements may also be reduced during the etch process 134, e.g., the highly selective chemical oxide remove process, as illustrated in FIG. 1f. After completion of the etch process 134, the patterned mask layer 126 may stripped from above the semiconductor device 100, and the surfaces 115s of the cavities 115n exposed to a pre-cleaning process well known to those having skill in the art in advance of epitaxially depositing a semiconductor material region in the cavities 115n, as will be discussed in detail below.

FIG. 1g shows the semiconductor device 100 of FIG. 1f in a further illustrative manufacturing stage, after the patterned mask layer 126 has been stripped and a pre-cleaning process in advance of epitaxial material deposition has been performed as described above. Thereafter, the semiconductor device 100 may be exposed to a deposition ambient 135 designed to epitaxially deposit silicon-containing semiconductor material regions 117 in the cavities 115n formed in the active area 105n of the NMOS device region 150N. The deposition ambient 135 may be based on any one of several recipes well known to those having skill in the art, such as silicon tetrachloride (SiCl₄), silane (SiH₄), dichlorosilane (SiH₂Cl₂), and the like, which may act as a source of silicon. Furthermore, in some illustrative embodiments—for example, when the epitaxially deposited semiconductor material regions 117 may substantially comprise silicon-carbon (Si:C)—the deposition ambient 135 may be adjusted to comprise carbon atoms, such that Si:C semiconductor material of the epitaxially deposited material regions may comprise silicon, with carbon present in the range of approximately 1-3 percent by weight.

As shown in the illustrative embodiment of FIG. 1g, the semiconductor device 100 may be exposed to the deposition ambient 135 such that the epitaxially deposited semiconductor material regions 117 are formed to a height 117h that substantially overfills the cavities 115n—i.e., wherein the upper surfaces of the epitaxially deposited semiconductor material regions 117 extend to a level above that of the interface between the base insulating layer 107 and the channel region 106n that may range from approximately 3-6 nm. In other illustrative embodiments, the epitaxially deposited semiconductor material regions 117 may be formed to a height 117h that is substantially flush with the interface between the base insulating layer 107 and the channel region 106n, whereas in still other embodiments, the cavities 115n may be underfilled by the epitaxially deposited semiconductor material regions 117—i.e., to a height 117h that may be approximately 3-6 nm below the interface between the base insulating layer 107 and the channel region 106n.

As is well known to those having skill in the art, during an epitaxial deposition process, the material comprising the silicon-based substrate acts as a “seed crystal.” Therefore, during the epitaxial deposition process, silicon-based materials will only be formed on the exposed surfaces, e.g., surfaces 115s, of silicon-containing semiconductor materials. On the other hand, surfaces that are covered by dielectric materials such as silicon nitride, silicon dioxide and the like, will be effectively “masked.” Therefore, as shown in

FIG. 1g, epitaxially deposited material will not be formed on, for example, the first conformal dielectric material layer 116 present above the PMOS device region 150P. Furthermore, epitaxially deposited material will not be formed on the trench isolation structures 104, the sidewall spacers 114s, or the third cap layer 113 of the cap layer stack 121n in the NMOS device region 150N.

While, in general, the silicon-based material comprising the semiconductor layer 103 —e.g., the NMOS active area 105n—will act as a “seed layer” during epitaxial deposition, the epitaxially deposited semiconductor material regions 117 may also take on a lattice structure and crystal orientation that is substantially identical to those of the semiconductor layer 103 in the active area 105n. Furthermore, the lattice structure of an unrestrained Si:C semiconductor material is generally smaller than the lattice structure of an unrestrained semiconductor material that is substantially silicon. Accordingly, when an Si:C semiconductor material is epitaxially deposited on a substantially crystalline silicon material —such as, for example, the semiconductor layer 103—the restrained lattice structure of the Si:C material may induce a localized stress on the surrounding lattice structure of the substantially silicon material. In this way, an epitaxially deposited semiconductor material region 117 comprising Si:C material formed in the cavities 115n of the active area 105n may induce a tensile stress (indicated by arrows 161) on the channel region 106n of the NMOS transistor elements formed in the device region 150N, thereby leading to an overall improvement in device performance, as previously described.

FIG. 1h schematically illustrates the semiconductor device 100 of FIG. 1g in a further advanced manufacturing stage. As shown in FIG. 1h, a second conformal dielectric material layer 118 may be formed above the semiconductor device 100 so as to cover the exposed surfaces thereof, including the first conformal dielectric material 116 present above the PMOS device region 150P, the trench isolation structures 104 and epitaxially deposited semiconductor material regions 117 of the NMOS device region 150N, and the sidewall spacer elements 114s and third cap layer 113 of the NMOS gate electrode structure 120n. In certain illustrative embodiments, the second conformal dielectric material layer 118 may comprise, for example, a layer of silicon dioxide material having a thickness in the range of 2-10 nm. Furthermore, as with the first conformal dielectric material layer 116, the second conformal dielectric material layer 118 may be formed using a highly conformal deposition process 136, such as MLD, ALD, CVD and the like.

FIG. 1i schematically depicts the illustrative semiconductor device 100 of FIG. 1h in yet a further manufacturing stage, wherein a mask layer 127, e.g., a photoresist material layer, has been formed above the semiconductor device 100 and patterned so as to cover the NMOS device region 150N and to expose the PMOS device region 150P. Thereafter, the semiconductor device 100 may then be exposed to an etch process 137 that may be adapted so as to be highly selective to the material comprising the second conformal dielectric material layer 118 (e.g., silicon dioxide) so as to expose the surfaces 115s of the cavities 115p —i.e., the semiconductor material of the active area 105p. For example, as previously described with respect to etch process 134 of FIG. 1f above, the etch process 137 may comprise a highly selective chemical oxide removal process, recipes for which are known in the art. Furthermore, the thickness of the third cap layer 113 of the cap layer stack 121p and the trench isolation regions formed in the PMOS device region 150P may also be reduced during the etch process 137, e.g., the highly selective chemical oxide remove process, also as previously described. After completion of the etch process 137, the patterned mask layer 127 may stripped from above the semiconductor device 100, and the surfaces 115s of the cavities 115p exposed to a pre-cleaning process in advance of epitaxially depositing a semiconductor material region in the cavities 115p, as will now be discussed.

FIG. 1j shows the semiconductor device 100 of FIG. 1i in yet a further illustrative manufacturing stage, after the patterned mask layer 127 has been stripped and a pre-cleaning process in advance of epitaxial material deposition has been performed as previously described. Thereafter, the semiconductor device 100 may be exposed to a deposition ambient 138 designed to epitaxially deposit silicon-containing semiconductor material regions 119 in the cavities 115p formed in the active area 105p of the PMOS device region 150P. In some illustrative embodiments, the epitaxially deposited semiconductor material regions 119 may comprise silicon-germanium (SiGe), in which case the deposition ambient 138 may be based on, for example, gaseous silicon sources such as silane (SiH₄), disilane (Si₂H₆), and/or trisilane (Si₃H₈), and gaseous germanium sources such as germane (GeH₄), digermane (Ge₂H₆), and/or trigermane (Ge₃H₈), and the like. Furthermore, in certain embodiments, the deposition ambient 138 may be adjusted so that relative concentrations of the gaseous silicon and germanium sources results in the epitaxially deposited semiconductor material regions 119 comprising a SiGe material having a germanium concentration in the range of 15-30% by weight. In other illustrative embodiments, the relative concentrations of the silicon and germanium precursor gases may be varied throughout the epitaxial deposition process, thereby resulting in an epitaxially deposited semiconductor material region 119 having a germanium concentration gradient. Depending on overall device requirements and processing strategy, in some embodiments the germanium concentration gradient may increasingly vary from the bottom surface 115s of the cavities 115p to the top surface of the epitaxially deposited semiconductor material region 119, whereas in other embodiments the germanium concentration gradient may decreasingly vary from bottom to top. In still other illustrative embodiments, the germanium concentration gradient may increasingly vary from the bottom surface 115s of the cavities 115p to an approximate midpoint of the epitaxially deposited semiconductor material region 119, and thereafter decreasingly vary to top of the region 119.

It should be noted that, as previously discussed with respect to the epitaxially deposited semiconductor material regions 117 formed in the NMOS region 150N, in certain illustrative embodiments the epitaxially deposited semiconductor material regions 119 may be formed to a height 119h that substantially overfills the cavities 115p—i.e., wherein the upper surfaces of the epitaxially deposited semiconductor material regions 119 extend to a level above that of the interface between the base insulating layer 107 and the channel region 106p that ranges between 3 nm and 6 nm. Furthermore, in other illustrative embodiments, the epitaxially deposited semiconductor material regions 119 may be formed to a height 119h that is substantially flush with the interface between the base insulating layer 107 and the channel region 106p, whereas in still other embodiments, the cavities 115p may be underfilled by the epitaxially deposited semiconductor material regions 119, such that the height 119h is approximately 3-6 nm below the interface between the base insulating layer 107 and the channel region 106p.

As previously discussed, the material comprising the silicon-based semiconductor layer 103 acts as a “seed crystal” during an epitaxial deposition process, and the epitaxially deposited semiconductor material regions 119 may take on a lattice structure and crystal orientation that is substantially identical to those of the semiconductor layer 103 in the active area 105p. However, contrary to the generally smaller lattice structure of an unrestrained Si:C semiconductor material as described above, the lattice structure of an unrestrained SiGe semiconductor material is generally larger than the lattice structure of an unrestrained semiconductor material that is substantially silicon. Accordingly, when an SiGe semiconductor material is epitaxially deposited on a substantially crystalline silicon material —such as, for example, the semiconductor layer 103—the restrained lattice structure of the SiGe material may also induce a localized stress on the surrounding lattice structure of the substantially silicon material. However, unlike the tensile stress that may be induced by a restrained Si:C material as discussed above, an epitaxially deposited semiconductor material region 119 comprising SiGe material formed in the cavities 115p of the active area 105p may induce a compressive stress (indicated by arrows 162) on the channel region 106p of the PMOS transistor elements formed in the device region 150P, thereby further enhancing overall device performance.

As described above, the embodiments illustrated by FIGS. 1f-1j teach a processing sequence wherein the epitaxially deposited semiconductor material regions 117 may be first formed in the NMOS device region 150N, and wherein the epitaxially deposited semiconductor material regions 119 are thereafter formed in the PMOS device region 150P. It should be understood that the above-described processing sequence may be reversed, that is, wherein the epitaxially deposited semiconductor material regions 119 may be formed in the PMOS device region 150P first, followed by forming the epitaxially deposited semiconductor material regions 117 in the NMOS device region 150N second. Generally speaking, therefore, the sequence of all other processing steps described in conjunction with FIGS. 1f-1j above may be adjusted as required to accomplish the reversed epitaxial deposition steps noted above.

FIG. 1k illustrates the semiconductor device 100 of FIG. 1j in a further manufacturing stage, wherein the second conformal dielectric material layer 118 may be removed from above the NMOS device region 150N. As shown in FIG. 1k, the semiconductor device 100 may be exposed to an etch process 139 adapted to selectively remove the dielectric material comprising the second conformal dielectric material layer 118. For example, in those embodiment wherein the second conformal dielectric material comprises silicon dioxide, the etch process 139 may be a wet isotropic etch process, such as a wet hydrofluoric (HF) acid process and the like. Furthermore, in those illustrative embodiments of the present disclosure wherein the third cap layers 113 of the cap layer stacks 121n, 121p may also comprise silicon dioxide, the third cap layers 113 may also be selective removed during the etch process 139, relative to the sidewall spacers 114s and the second cap layer 112, both of which may comprise, for example, silicon nitride.

After completion of the etch process 139, the semiconductor device 100 may then be exposed to an etch process 140 adapted to remove the second cap layers 112 of the cap layer stacks 121n and 121p, as shown in FIG. 1l. In certain illustrative embodiments, the etch process 140 may be, for example, a dry anisotropic etch process such as a reactive ion etch (RIE) process, and the like. Additionally, in some embodiments, the first cap layer 111 of the cap layer stacks 121n, 121p may act as an etch stop or etch indicator layer during the etch process 140. Accordingly, the etch recipe of the etch process 140 may be adapted to selectively remove the material comprising the second cap layers 112—such as, for example, silicon nitride—relative to the material comprising the first cap layers 111—such as, for example, silicon dioxide.

After completion of the etch process 140, the sidewall spacer elements 114s remain in place adjacent to the sidewalls of the gate electrode structures 120n, 120p as shown in FIG. 1l, and as may be required for transistor elements based on HK/MG architecture. Thereafter, in some illustrative embodiments, further processing of the semiconductor device 100 may proceed, such as halo region implantations based on the sidewall spacer elements 114s, forming additional spacer elements (not shown) to facilitate drain and source region implantations, and the like. In other embodiments of the present disclosure, such as, for example, when conventional polySiON gate electrode configurations are contemplated, the entire cap layer stacks 121n, 121p and sidewall spacer elements 114s may be removed from the gate electrode structures 120n and 120p during the etch process 140, followed by new spacer element formation (not shown) to facilitate halo and/or drain and source region implantation steps, and the like.

As a result of the presently disclosed subject matter, dual cavities and embedded stressor regions may be formed in the active areas of semiconductor devices having different conductivity types, such as NMOS and PMOS transistor elements. Moreover, since the dual cavities are formed in the active areas of both semiconductor device types during a common etching step, the overall processing complexity may be substantially reduced, thereby leading higher device yield and greater performance reliability.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention.

Accordingly, the protection sought herein is as set forth in the claims below.

What is claimed:

1. A method, comprising:
forming a first material in first cavities formed in a first active area adjacent to a first channel region of a semiconductor device, wherein said first material induces a first stress in said first channel region; and
forming a second material in second cavities formed in a second active area adjacent to a second channel region of said semiconductor device, wherein said second material induces a second stress in said second channel region that is of an opposite type of said first stress in said first channel region, and wherein said first and second cavities are formed during a common etch process.

2. The method of claim 1, wherein forming said first cavities in said first active area comprises forming said first cavities on opposite sides of said first channel region, and wherein forming said cavities in said second active area comprises forming said second cavities on opposite sides of said second channel region.

3. The method of claim 1, wherein forming said first material comprises performing an epitaxial deposition process to form a first semiconductor material that is different from a semiconductor material comprising said first active area.

4. The method of claim 3, wherein forming said second material comprises performing an epitaxial deposition process to form a second semiconductor material that is different from said first semiconductor material and different from a semiconductor material comprising said second active area.

5. The method of claim 4, wherein inducing said first stress comprises inducing a tensile stress, and wherein inducing said second stress comprises inducing a compressive stress.

6. A method, comprising:
forming a first gate electrode structure above a first active area and a second gate electrode structure above a second active area of a semiconductor device;
forming first and second cavities adjacent to first and second channel regions below said first and second gate electrode structures, respectively, during a common etch process;
forming a first stressed semiconductor material in said first cavities, said first stressed semiconductor material inducing a first type of stress in said first channel region; and
forming a second stressed semiconductor material in said second cavities, said second stressed semiconductor material inducing a second type of stress in said second channel region that is opposite of said first type of stress in said first channel region.

7. The method of claim 6, further comprising forming said first cavities to a first depth in said first active area and forming said second cavities to a second depth in said second active area, wherein said second depth is substantially the same as said first depth.

8. The method of claim 6, further comprising forming a spacer layer over said first and second gate electrode structures prior to forming said first and second cavities.

9. The method of claim 6, wherein forming said spacer layer comprises forming a dielectric material layer comprising silicon nitride.

10. The method of claim 8, further comprising forming a cap layer stack above said first and second gate electrode structures prior to forming said spacer layer.

11. The method of claim 10, wherein forming said cap layer stack comprises forming a first cap layer comprising silicon dioxide, a second cap layer comprising silicon nitride above said first cap layer, and a third cap layer comprising silicon dioxide above said second cap layer.

12. The method of claim 6, wherein forming said first stressed semiconductor material comprises selectively covering said second active area with a first dielectric cover layer and performing an epitaxial deposition process.

13. The method of claim 12, wherein forming said second stressed semiconductor material comprises selectively covering said first active area with a second dielectric cover layer and performing an epitaxial deposition process.

14. The method of claim 12, wherein selectively covering said second active area with said first dielectric cover layer comprises forming said first dielectric cover layer above said first and second active areas and performing a selective etch process to remove said first dielectric cover layer from above said first active area, wherein said first dielectric cover layer comprises silicon dioxide.

15. The method of claim 13, wherein selectively covering said first active area with said second dielectric cover layer comprises forming said second dielectric cover layer above said first and second active areas and performing a selective etch process to remove said first and second dielectric cover layers from above said second active area, wherein said first and second dielectric cover layers comprise silicon dioxide.

16. The method of claim 6, wherein forming said first stressed semiconductor material comprises forming silicon-carbon, and wherein inducing said first type of stress comprises inducing a tensile stress.

17. The method of claim 6, wherein forming said second stressed semiconductor material comprises forming silicon-germanium, and wherein inducing said second type of stress comprises inducing a compressive stress.

18. A method, comprising:
forming first cavities in an active area of an NMOS transistor element, wherein said first cavities are formed on either side of a channel region of said NMOS transistor element;
forming second cavities in an active area of a PMOS transistor element, wherein said second cavities are formed on either side of a channel region of said PMOS transistor element, and wherein said first and second cavities are formed during a common etch process;
forming a silicon-carbon semiconducting material in said first cavities, said silicon-carbon semiconducting material creating a tensile stress in said channel region of said NMOS transistor element; and
forming a silicon-germanium semiconducting material in said second cavities, said silicon-germanium semiconducting material inducing a compressive stress in said channel region of said PMOS transistor element.

19. The method of claim 18, further comprising forming a first cap layer stack above a gate electrode structure of said NMOS transistor element, a second cap layer stack above a gate electrode structure of said PMOS transistor element, and a spacer material layer above each of said gate electrode structures of said NMOS and PMOS transistor elements prior forming said first and second cavities.

20. The method of claim 18, wherein forming said silicon-carbon semiconducting material comprises covering at least said second cavities with a conformal cover layer comprising silicon dioxide and performing an epitaxial deposition process.

21. A semiconductor device, comprising:
a PMOS transistor element, said PMOS transistor element comprising a first gate electrode structure, a first gate dielectric layer, and a first channel region;
a silicon-germanium material region at least partially embedded in a first active area of said semiconductor device on opposites sides of said first gate electrode structure, wherein said silicon-germanium material region extends to a first depth below said gate dielectric layer and is adapted to induce a compressive stress in said first channel region;
an NMOS transistor element, said NMOS transistor element comprising a second gate electrode structure, a second gate dielectric layer, and a second channel region; and
a silicon-carbon material region at least partially embedded in a second active area of said semiconductor device on opposites sides of said second gate electrode structure, wherein said silicon-carbon material region extends to a second depth below said gate dielectric layer and is adapted to induce a tensile stress in said second channel region, and wherein said second depth is substantially the same as said first depth.

22. The semiconductor device of claim 21, wherein at least one of said first and second gate dielectric layers comprises at least one of tantalum oxide, strontium titanium oxide, hafnium oxide, hafnium silicon oxide, and zirconium oxide, and at least one of said first and second gate electrode structures comprises at least one of titanium nitride, titanium-aluminum, titanium aluminum nitride, and titanium silicon nitride.

23. The semiconductor device of claim 21, wherein at least one of said first and second gate dielectric layers comprises at least one of silicon dioxide and silicon oxynitride, and at least one of said first and second gate electrode structures comprises polysilicon.

24. The semiconductor device of claim 21, wherein at least one of said PMOS and NMOS transistor elements comprises a cap layer stack above at least one of said first and second gate electrode structures, respectively, said cap layer stack comprising first cap layer comprising silicon dioxide, a second cap layer comprising silicon nitride above said first cap layer, and a third cap layer comprising silicon dioxide above said second cap layer.

25. The semiconductor device of claim 21, wherein at least one of said PMOS and NMOS transistor elements comprises sidewall spacer elements adjacent to sidewalls of at least one of said first and second gate electrode structures, respectively, said sidewall spacer elements comprising silicon nitride.
